(19) United States
(12) Patent Application Publication
(10) Pub. No.: US 2024/0363382 A1
(43) Pub. Date: Oct. 31, 2024

(54) METHODS AND MECHANISMS FOR DAMPING VIBRATIONS IN SUBSTRATE TRANSFER SYSTEMS

(71) Applicant: Applied Materials, Inc., Santa Clara, CA (US)

(72) Inventor: Ulrich Oldendorf, Ober-Ramstadt (DE)

(21) Appl. No.: 18/140,155

(22) Filed: Apr. 27, 2023

(51) Int. Cl. H01L 21/677; B65G 54/02; F16F 15/00

(52) U.S. Cl. CPC H01L 21/67709; B65G 54/02; F16F 15/002

(57) ABSTRACT

An electronic device manufacturing system including a substrate carrier configured to secure a substrate during processing and a controller, operatively coupled to the substrate carrier. The controller is configured to perform operations comprising receiving a set of input values associated with moving the substrate carrier from a first position to a second position along a magnetic levitation track. The operations further comprise determining, based on the set of input values, one or more corrective signals to apply to the substrate carrier during movement of the substrate carrier along the magnetic levitation track. The operations further comprise generating a magnetic field to move the substrate carrier on a direction along the magnetic levitation track and applying, to the substrate carrier, the one or more corrective signals to reduce vibrations that would be experienced by a substrate held by the substrate carrier due to a motion of the substrate carrier.

### TECHNICAL FIELD

The present disclosure relates to the field of robotics, and, more particularly, to damping vibrations in substrate transfer systems, which transport substrates between process chambers within an isolated environment. The substrates may be transported using a magnetic levitation platform within a transport enclosure.

### BACKGROUND

Semiconductor devices are formed on substrates through numerous process steps within one or more process chambers of a semiconductor manufacturing system. Each process chamber completes one or more of the various steps (e.g., etching, polishing, deposition, etc.) to form the semiconductor devices. The process chambers are held under vacuum. Substrate transfer systems, which are also held under vacuum, can interconnect process chambers and move the substrates between the process chambers without having to break vacuum. Some substrate transfer systems have a linear and rectangular arrangement such that process chambers are positioned along each side of the transfer chamber.

A substrate transfer system using a linear arrangement typically includes a conveyor having a rectangular top surface with the process chambers on one side or opposite sides of the conveyor. The conveyor can be connected to one or more load locks in order to maintain the vacuum environment within the transfer system. Substrates are placed in and removed from the load lock, which will only open to the transfer chamber once under vacuum. One or more robots can be positioned near the process chambers and load lock to transfer the substrates between the conveyor and the process chambers or load lock.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an aspect of the disclosure, an electronic device manufacturing system includes a substrate carrier configured to secure a substrate during processing and a controller operatively coupled to the substrate carrier. The controller is configured to perform operations comprising receiving a set of input values associated with moving the substrate carrier from a first position to a second position along a magnetic levitation track. The operations further comprise determining, based on the set of input values, one or more corrective signals to apply to the substrate carrier during movement of the substrate carrier along the magnetic levitation track. The operations further comprise generating a magnetic field to move the substrate carrier on a direction along the magnetic levitation track and applying, to the substrate carrier, the one or more corrective signals to reduce vibrations that would be experienced by a substrate held by the substrate carrier due to the motion of the substrate carrier.

A further aspect of the disclosure includes a method according to any aspect or implementation described herein.

A further aspect of the disclosure includes a non-transitory computer-readable storage medium comprising instructions that, when executed by a processing device operatively coupled to a memory, performs operations according to any aspect or implementation described herein.

### BRIEF DESCRIPTION OF THE DRAWINGS

The present disclosure is illustrated by way of example, and not by way of limitation in the figures of the accompanying drawings.

FIG. 1A depicts a top view of a substrate transfer system according to various implementations.

FIG. 1B depicts a longitudinal side view of a substrate transfer system according to various implementations.

FIG. 1C depicts a lateral side view of a substrate transfer system according to various implementations.

FIG. 1D depicts a substrate carrier according to various implementations.

FIG. 2A depicts a top view of a magnetic levitation platform according to various implementations.

FIG. 2B depicts an example a substrate carrier for use with magnetic levitation platforms according to various implementations.

FIG. 3 depicts a magnetic levitation platform having upper and lower magnetic levitation tracks according to various implementations.

FIG. 4 depicts a perspective view of a magnetic levitation platform and substrate carrier according to various implementations.

FIGS. 5A-B are illustrations of a magnetic levitation platform, according to aspects of the present disclosure.

FIG. 6A is block diagram of an example system controller 600, according to certain implementations.

FIG. 6B is block diagram of another example system controller 602, according to certain implementations.

FIG. 7 is a flow chart of a method for performing damping operations on the substrate carrier, according to certain implementations.

FIG. 8 is a graph illustrating end effector displacement during active damping and passive damping, according to certain implementations.

FIG. 9 is a block diagram illustrating a computer system, according to certain implementations.

### DETAILED DESCRIPTION

Described herein are technologies directed to methods and mechanisms for damping vibrations in substrate transfer systems during transport of substrates (e.g., during substrate manufacturing). An electronic device manufacturing system can be configured to perform one or more manufacturing processes (e.g., deposition process, etch process, polishing process, etc.) upon a substrate in one or more process chambers. For example, during a deposition process (e.g., a deposition (CVD) process, an atomic layer deposition (ALD) process, and so forth), a film can be deposited on the surface of a substrate. The manufacturing system can use one or more robots to position the substrate onto a substrate-holder (e.g. a “chuck”) inside the process chamber.

The manufacturing system can include a transfer chamber having a magnetic levitation platform (also referred to herein as a magnetic levitation system) for use in a semiconductor manufacturing system. The magnetic levitation platform can include a network of magnetic levitation tracks (also referred to herein as “lanes”) that can move substrates from one position to another within the transfer chamber without breaking vacuum. The magnetic levitation platform can provide access to process chambers and load locks connected to a transfer chamber in which the magnetic levitation platform is located. In some implementations, the magnetic levitation platform can include one or more longitudinal magnetic levitation track that runs along the length of a chamber and one or more lateral magnetic levitation track that runs along the width of the chamber. The lateral tracks may run at an angle (e.g., at about 90°) with respect to the longitudinal tracks such that a plane of each lateral track intersects a plane of each longitudinal track at one or more junctions. At least one substrate carrier can be configured to move linearly along a longitudinal track or a lateral track. At a junction, a substrate carrier can be configured to switch from a longitudinal track to a lateral track, or vice versa, and change direction. The substrate carrier can be configured to rotate at the junctions. For example, the substrate carrier can be configured to rotate about ±90° to about ±180° at one or more junctions. A substrate carrier can include a mover and an end effector. A mover can be operable by a standard energy coupling (e.g., an electrical wire) and one or more magnets. The mover can be coupled to an end effector configured to hold a substrate. The mover can raise or lower the end effector using, for example, mechanical and/or magnetic forces.

In some instances, movement of the substrate carrier along the magnetic levitation tracks or lifting of the substrate carrier and/or end effector can cause vibrations in the held substrate. For example, the acceleration and the deceleration of the substrate carrier can cause the substrate to experience vibrations. Once the substrate carrier reaches it's a target position and stops, the vibrations can oscillate through the substrate for a relatively significant time (e.g., half a second to a second or more). The vibrations can, thus, delay a robot from removing the substrate from the substrate carrier and positioning the substrate onto a substrate-holder inside the process chamber or inside a load lock. These delays can decrease system throughput by increasing the time taken to position the substrate at a target location.

Aspects and implementations of the present disclosure address these and other shortcomings of the existing technology by damping vibrations in substrate transfer systems. In particular, the system controller can receive instructions to move the substrate carrier from an initial position to a destination. The instructions can include mover movement data, which reflects the target movement parameters of the substrate carrier as well as the position data of the mover. For example, the mover movement data can include one or more of the movement start time of the mover, the movement end time of the mover, the acceleration rate of the mover, the deceleration rate of the mover, the velocity of the mover, the movement direction of the mover (e.g., vertical movement, horizontal movement, etc.), the current position of the mover, the target position of the mover, etc. In some implementations, the system controller can also receive substrate data indicative of parameters related to the substrate. The substrate data can include, for example, one or more of the mass or weight of the substrate, the location of the center of gravity of the substrate, the density of the substrate, the natural frequency of the substrate, the thickness of the substrate, the radius or diameter of the substrate, the material(s) included in the substrate, etc.

The system controller can use the mover movement data and/or the substrate data to determine a set of corrective signals to apply to the substrate carrier during and after transit of the substrate. The corrective signals can be applied to one or more component (e.g., bearings, coil, etc.) housed in the mover, to one or more component on the magnetic levitation tracks, or any combination thereof. In some implementations, the system controller can perform a lookup in a reference table (e.g., metadata table) to determine the corresponding corrective signal(s) related to the mover movement data and/or substrate data. Each corrective signal (e.g., a current, voltage, an instruction, etc.) can be applied during a particular time slice of the transit (and after the transit).

The corrective signals can be used to reduce or prevent the vibration of the substrate during and after transit of the substrate. In some implementations, the corrective signals can alter one or more of the levitation, acceleration, deceleration, or velocity of the mover. In some implementations, the corrective signals can be applied to the magnetic bearings and/or coils in the mover to dampen the vibrations generated by the movement produced by the magnetic levitation tracks. In some implementations, the corrective signals can be configured to raise or lower the end effector to dampen the vibrations, or any combination of the above can be used. As such, the corrective signals allow the system controller to perform proactive damping rather than reactive damping (e.g., performing damping in response to receiving feedback during or after transit).

Aspects of the present disclosure result in technological advantages of preventing or reducing substrate vibration during and after transit on a substrate transfer system. This results in the technological advantages of a significant reduction in time required to transfer substrate to a robot. Thus, the present disclosure can increase system throughput.

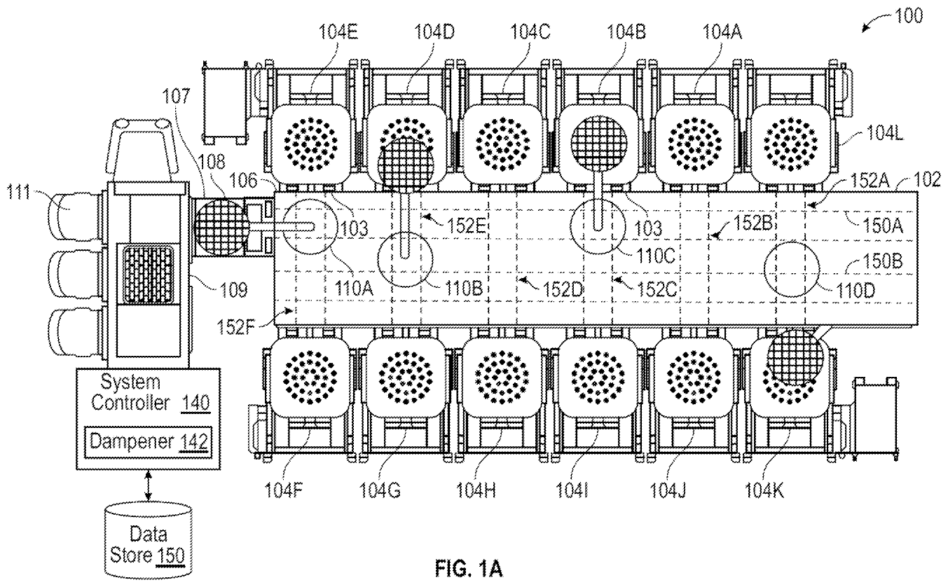

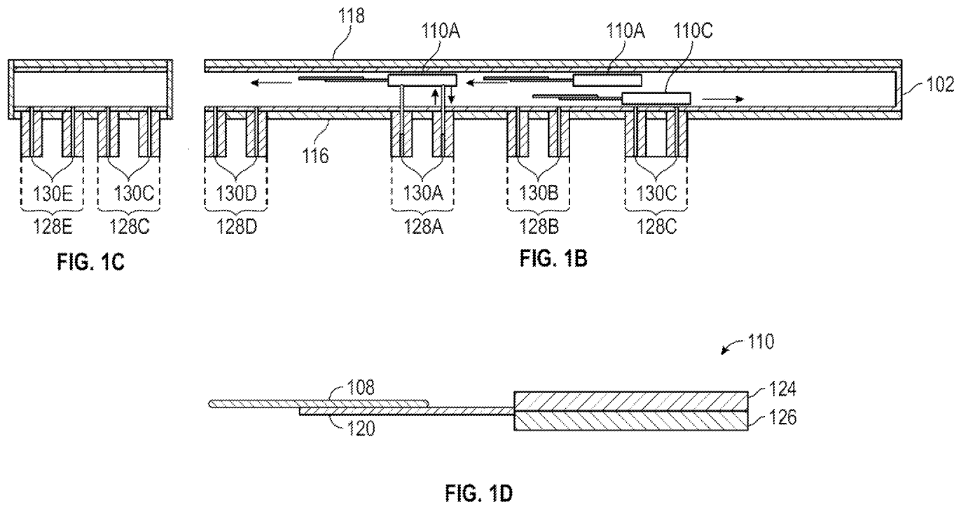

FIGS. 1A-C illustrate a manufacturing system 100, according to aspects of the present disclosure. FIG. 1A depicts a top view of manufacturing system 100 according to various implementations. FIG. 1B depicts a longitudinal side view of manufacturing system 100 according to various implementations. FIG. 1C depicts a lateral side view of manufacturing system 100 according to various implementations.

Referring to FIGS. 1A-C, transfer chamber 102 can include at least one port 103 configured to permit access to at least one process chamber (also referred to as processing chambers) 104A-L. In some implementations, the transfer chamber 102 can have a set of ports 103, where each of the ports is configured to permit access to one of a set of process chambers 104A-L disposed therearound transfer chamber 102 and coupled thereto. Each port 103 can include a slit valve that is sized to receive an end effector holding a substrate (e.g., a wafer). In some implementations, all of the ports 103 and/or slit valves are co-planar and share a common height. Alternatively, different ports 103 and/or slit valves can be positioned at different heights and/or planes. Additionally, in some implementations, all ports 103 and/or slit valves have a common opening pitch (vertical dimension of the opening). The common opening pitch can be a single height pitch that can receive an end effector and substrate positioned at a specific height or a multi-height pitch that can receive end effectors and substrates positioned at multiple different heights. For example, end effectors and substrates of substrate carriers attached to a bottom track as well as end effectors and substrates of substrate carriers attached to a top track. Alternatively, different ports 103 can have different opening pitches.

According to some implementations, transfer chamber 102 can have a length and a width, where the first dimension (referred to as a longitudinal direction) of the length is greater than the second dimension (referred to as a lateral direction) of the width. Ports 103 can be disposed along the length of transfer chamber 102. In some implementations, ports 103 can be oriented approximately orthogonal to the length of transfer chamber 102. In some implementations, transfer chamber 102 can further include load lock port 106 configured to permit access to load lock 107 (or multiple additional ports each configured to permit access to one or more load locks). The load lock port 106 can be disposed at the first end of transfer chamber 102 along the width of transfer chamber 102. In some implementations, port 106 can be approximately orthogonal to port(s) 103. Load lock 107 can be connected to factory interface 109 containing one or more front opening unified pods (FOUPs) 111. In some implementations, one or more additional ports (not shown) can be positioned at an opposite end of transfer chamber 102 from load lock port 106, and can be configured to permit access to one or more load locks 107 and/or process chambers 104. Factory interface 109 can contain a robot (not shown) that transfers substrates from FOUPs 111 and places them in load lock 107 for the substrate carriers 110A-D to retrieve them from load lock 107.

Manufacturing system 100 can include at least one substrate carrier 110A-110D configured to transfer a substrate 108 between the at least one process chamber 104A-104L and the transfer chamber 102. According to some implementations, the transfer chamber 102 can contain a set of substrate carriers 110A-110D.

Each substrate carrier 110A-110D can be configured to move using a magnetic levitation conveyor system (e.g., one or more linear motors). For example, each substrate carrier 110A-110D can move along at least one magnetic levitation track 150A-B, 152A-F. According to some implementations, the transfer chamber 102 can include two (or more) longitudinal magnetic levitation tracks 150A, 150B and multiple lateral magnetic levitation tracks 152A, 152B, 152C, 152D, 152E, 152F. Each magnetic levitation track can include a respective stator of a linear motor. In some implementations, longitudinal magnetic levitation tracks are positioned on a bottom interior surface 116 of transfer chamber 102 and lateral magnetic levitation tracks 152A-F are positioned on an opposite, top interior surface 118 of the transfer chamber 102. Longitudinal magnetic levitation tracks 150A-B can be configured to move substrate carriers 110A-D in a forward and backward direction (away from and towards the load lock 107) while lateral magnetic levitation tracks 152A-F can be configured to move substrate carriers 110A-D towards and away from process chambers 104 connected to the length of transfer chamber 102 (e.g., perpendicular to the longitudinal axis of the transfer chamber).

In some implementations, the longitudinal magnetic levitation tracks 150A-B are positioned at the top of transfer chamber 102, and lateral magnetic levitation tracks 152A-F are positioned at the bottom of transfer chamber 102. In some implementations, longitudinal levitation tracks 150A-B can be positioned at the top and/or bottom of transfer chamber 102, and lateral magnetic levitation tracks can also be positioned at that top and/or bottom of transfer chamber 102. Magnetic levitation tracks can be in a facing arrangement (e.g., with any magnetic levitation track(s) on the bottom of the transfer chamber in a face-up orientation and any magnetic levitation tracks on the top of the transfer chamber in a face-down orientation) as shown in FIG. 1B. In some implementations, the upper tracks and the lower tracks may be spaced apart.

According to some implementations, longitudinal magnetic levitation tracks 150A-B can be configured to move one or more of substrate carriers 110A-D along the length (e.g., along a longitudinal axis) of transfer chamber 102. Lateral magnetic levitation tracks 152A-F can be configured to move one or more substrate carriers 110A-D along a lateral axis that is orthogonal to the longitudinal axis of transfer chamber 102. In some implementations, longitudinal magnetic levitation track 150A moves substrate carriers 110A-D in one direction (e.g., away from the load lock 107) and longitudinal magnetic levitation track 150B moves substrate carriers 110A-D in an opposite direction (e.g., toward the load lock 107). Substrate carriers 110A-D can be transferred between longitudinal magnetic levitation tracks 150A-B via lateral magnetic levitation tracks 152A-F.

In some implementations, as shown, the width of transfer chamber 102 can be too narrow to enable a substrate carrier positioned proximate to a process chamber to rotate in a manner that causes a held substrate to be directed towards that process chamber. In such implementations, in order to place a substrate into a process chamber (e.g., process chamber 104D), a substrate carrier (e.g., substrate carrier 1101B) can be positioned at an intersection of a lateral track and a longitudinal track on an opposite side of the transfer chamber to the process chamber into which the substrate will be placed. The substrate carrier can then rotate towards the process chamber until it is approximately lined up with the lateral track (and perpendicular to the longitudinal track). The substrate carrier can then move along the lateral track towards the process chamber to place the substrate into the process chamber. After placement of the substrate in the process chamber, the substrate carrier can move in the opposite direction until it is again at the intersection of a lateral track and a longitudinal track opposite the process chamber, and can then rotate so that it faces in the longitudinal direction.

FIG. 1D shows an illustration of a substrate carrier 110 suitable for use in the manufacturing system 100, according to aspects of the present disclosure. The substrate carrier 110 can include end effector 120 for receiving, lifting and holding a substrate 108, and/or on which substrate 108 can be placed. Any suitable end effector 120 for use in a semiconductor processing or manufacturing system can be used as would be understood by those of ordinary skill in the art. According to some implementations, the one or more substrate carriers 110 can be a robot arm as known to those of ordinary skill in the art. Substrate carrier 110 can include upper magnetic portion 124 and lower magnetic portion 126. Lower magnetic portion 126 can be, for example, a first mover of a first linear motor. Upper magnetic portion 124 can be, for example, a second mover of a second linear motor. Alternatively, the upper magnetic portion and the lower magnetic portion may be upper and lower halves of a single mover that is configured to engage with a first stator below substrate carrier 110 and a second stator above substrate carrier 110. The upper magnetic portion 124 may include one or more magnets (e.g., permanent magnets), and the lower magnetic portion 126 may include one or more additional magnets. The upper and lower magnetic portions can be configured such that their magnetic fields do not interfere with one another. The magnetic levitation conveyor system includes one or more electromagnets (not shown) for controlling movement of the substrate carriers and linear motors (not shown) for moving the substrate carriers 110, 110A-110D.

Referring back to FIGS. 1A-1C, according to some implementations, the set of ports 103 can be or include a set of slit valves. A first transfer plane of at least a first subset of the plurality of slit valves is accessible to the substrate carriers engaged with the magnetic levitation tracks disposed on the bottom surface of transfer chamber 102. A second transfer plane of a second subset of the plurality of slit valves can be accessible to substrate carriers engaged with the magnetic levitation tracks disposed on the top surface of the transfer chamber. To further improve throughput and enable approximately simultaneous swapping of substrates in process chamber 104A-L or load lock 107, at least some of the set of slit valves have a first substrate transfer plane and a second substrate transfer plane that is above the first substrate transfer plane. The first substrate transfer plane can be accessible to substrate carriers that are engaged with the magnetic levitation tracks on the bottom surface. The second substrate transfer plane can be accessible to substrate carriers that are engaged with magnetic levitation tracks on the top surface. In further embodiments, the plurality of slit valves can have a common transfer plane accessible to substrate carriers that are engaged with the magnetic levitation tracks on the bottom surface as well as to substrate carriers that are engaged with the magnetic levitation tracks on the top surface. The slit valve openings can be sized according to the configuration of the transfer planes.

According to embodiments, the system can include a first load lock and a second load lock (not shown). The first load lock can be accessible to substrate carriers that are engaged with the magnetic levitation track on the bottom surface. The second load lock can be stacked above the first load lock at the end of transfer chamber 102. The second load lock can be accessible to substrate carriers that are engaged with the magnetic levitation track(s) on the top surface. In some implementations, a first height of transfer chamber 102 at the end near the first load lock can be greater than a second height of a remainder of transfer chamber 102. In some implementations, the first load lock and the second load lock can be arranged in a side-by-side configuration at an angle relative to the length of the transfer chamber (e.g., a 30- or 45-degree angle).

According to some implementations, the system 100 includes at least one vertical motion assembly 128A-128E configured to receive a substrate 108 and to lift and/or lower the substrate between transfer planes and/or between magnetic levitation tracks. The vertical motion assembly 128A-128E can include one or more lift pins, for example, a pair or trio of lift pins 130A-130E. Alternatively, the vertical motion assembly can move substrate carriers using electromagnetism, lift plates (e.g., rotatable lifts), and/or other lift mechanisms, some of which are described in greater detail below. In the example of a lift pin assembly, the lift pins 130A-130E can be configured to pass through the bottom surface 116 of the transfer chamber 102 and may have an atmospheric-facing side and a vacuum-facing side. The atmospheric-facing side can be outside of the bottom surface of transfer chamber 102. The lift pins 130A-130E can be enclosed in a bellows to maintain the vacuum environment in the transfer chamber. The lift pins 130A-130E can be configured to extend into the transfer chamber 102 on the vacuum-facing side. In some implementations, the at least one vertical motion assembly 128A-128E can be configured to move a substrate carrier 110 that is positioned in front of the first load lock in a vertical direction to cause the substrate carrier 110 to reach a transfer plane above the second height of the remainder of transfer chamber 102 (discussed above). During operation, when a lift pin 130A-130E or other lift mechanism lifts a substrate carrier 110, 110A-110D to a certain proximity with the top track, a magnetic field can be activated in the proximity of a substrate carrier. The magnetic field in the proximity of the substrate carrier 110, 110A-110D can be deactivated when a lift pin 130A-130E or other lift mechanism engages with the substrate carrier 110, 110A-110D on the top track to move the substrate to the lower track via the lift pin 130A-130E.

Manufacturing system 100 can also include a system controller 140. System controller 140 can be and/or include a computing device such as a personal computer, a server computer, a programmable logic controller (PLC), a microcontroller, a proportional-integral-derivative (PID) controller and so on. System controller 140 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 140 can include a data storage device (e.g., one or more disk drives and/or solid state drives), a main memory, a static memory, a network interface, and/or other components. System controller 140 can execute instructions to perform any one or more of the methodologies and/or implementations described herein. In some implementations, system controller 140 can execute instructions to perform one or more operations at manufacturing system 100 in accordance with a process recipe. The instructions can be stored on a computer readable storage medium, which can include the main memory, static memory, secondary storage and/or processing device (during execution of the instructions).

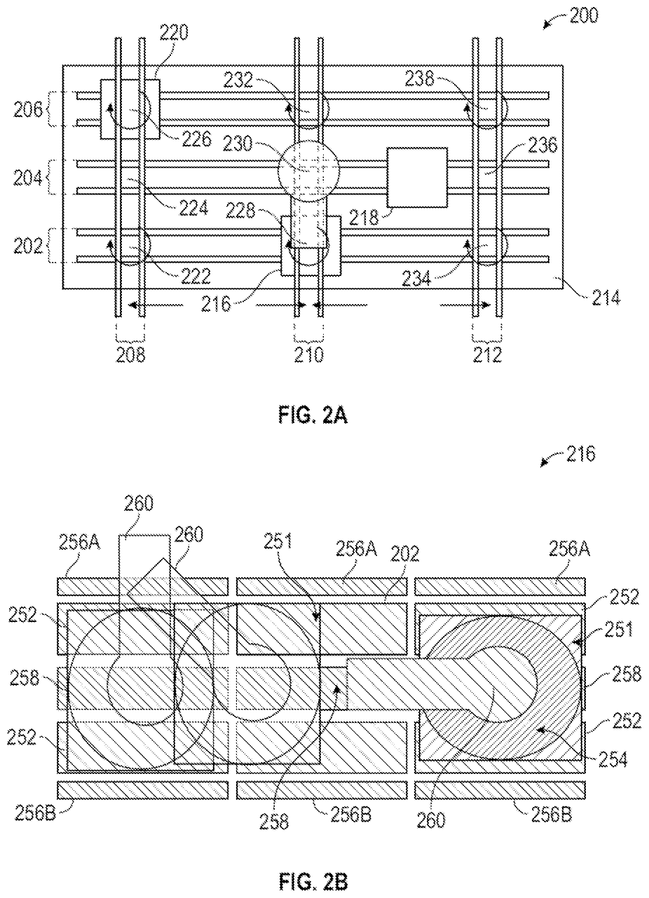

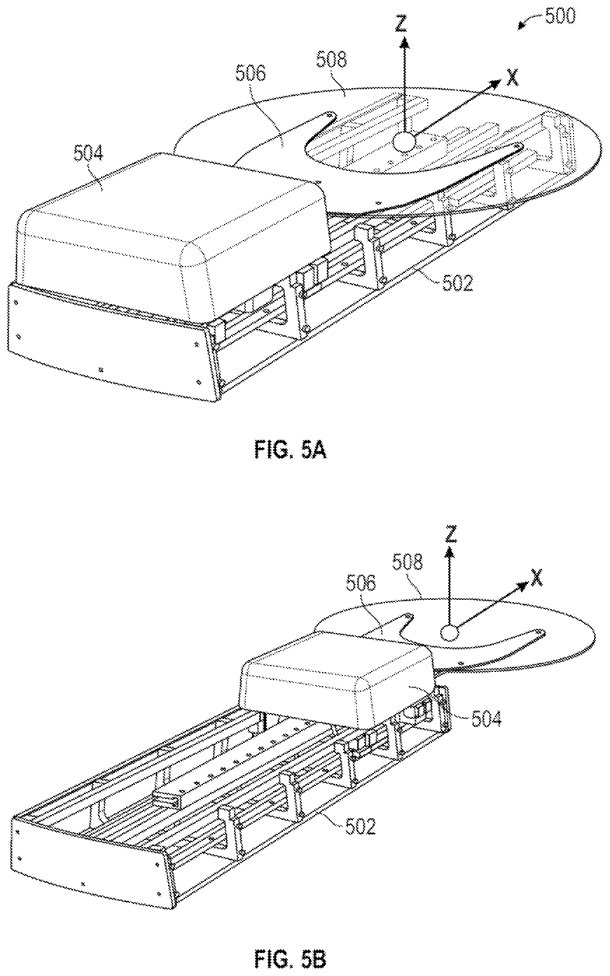

System controller 140 can receive data from sensors included on or within various portions of manufacturing system 100 (e.g., process chambers 104A-L, transfer chamber 102, load lock 107, substrate carrier 110A-110D, magnetic levitation tracks 150A, 150B, 152A-152F, etc.). In some implementations, data received by system controller 140 can include data related to the substrate (referred to as substrate data), such as the mass or weight of the substrate, the location of the center of gravity of the substrate, the density of the substrate, the natural frequency of the substrate, the thickness of the substrate, the radius or diameter of the substrate, the material(s) included in the substrate, etc. Such data can be obtained using one or more sensor in substrate carrier 110A-110D, magnetic levitation tracks 150A, 150B, 152A-152F, etc., or obtained from data store 150. In some implementation, data received by system controller 140 can include data related to the movement of a mover (e.g., mover 251 of FIG. 2B, mover 504 of FIG. 5A-B, etc.), also referred to as mover movement data, such as the movement start time of the mover, the movement end time of the mover, the acceleration rate of the mover, the deceleration rate of the mover, the velocity of the mover, the movement direction of the mover (e.g., vertical movement, horizontal movement, etc.), the initial position of the mover, the final position of the mover, etc. In some implementations, data received by the system controller 140 can include spectral data and/or non-spectral data for a portion of substrate 108. In other or similar implementations, data received by the system controller 140 can include data associated with processing substrate 108 at process chamber 104A-L. For purposes of the present description, system controller 140 is described as receiving data from sensors included within substrate carrier 110A-110D, magnetic levitation tracks 150A, 150B, 152A-152F, and/or data store 150. However, system controller 140 can receive data from any portion of manufacturing system 100 and can use data received from the portion in accordance with implementations described herein. Data received from sensors of the various portions of manufacturing system 100 can be stored in a data store 150. Data store 150 can be included as a component within system controller 140 or can be a separate component from system controller 140.

System controller 140 can include dampener 142. Dampener 142 can reduce the vibrations experienced by substrate 108 due to external forces (e.g., movement of the substrate carrier and/or mover, external vibrations, etc.). In some implementations, dampener 142 can send a corrective signal to system controller 140 to reduce and/or remove the vibrations experienced by the substrate during or after movement of substrate carrier 110, 110A-D. The corrective signal can include a current, a voltage, an instruction, etc. The corrective signal can be applied to the one or more components (e.g., bearings, coil, etc.) of the mover and/or of the tracks. In some implementations, the corrective signals can alter one or more of the levitation, acceleration, deceleration, or velocity of the mover (e.g., to increase and/or decrease the velocity of the mover, to increase and/or decrease the acceleration of the mover, raise and/or lower the levitation of the mover, etc.). In some implementations, the corrective signals can be applied to the bearings and/or coils in the mover to dampen the vibrations generated by the movement produced by magnetic levitation tracks. In some implementations, the corrective signals can be configured to raise or lower the end effector to dampen the vibrations. The corrective signals can be used to reduce or remove the vibration of the substrate during and after transit. In particular, the corrective signals can be used to move the mover and/or end effector to counter or cancel the vibrations produced in the substrate during and/or after transit.

In some implementations, a corrective signal can be applied each predetermined time slice during the movement (transit) or post-movement of the mover. For example, the corrective signal can be applied for each 10 milliseconds during the movement of the mover, and for 100 millisecond after movement of the mover ends.

Dampener 142 can receive, as input, data related to the current or target movement of the mover, data related to the substrate (e.g., weight or mass of the substrate, natural frequency of the substrate, etc.), data related to environmental factors (e.g., pressure, air composition, etc., which can be stored on data store 150). Dampener 142 can then, based on the input, select one or more corrective signals and apply the selected corrective signal(s) to the mover, tracks, and/or end effector. In one implementation, to select the corrective signal(s), dampener 142 perform a lookup in a reference table (e.g., metadata table). In an illustrative example, based on the start time of the acceleration of the mover, the end time of the acceleration of the mover, the start time of the deceleration of the mover, and the end time of the deceleration of the mover, and the weight of the substrate, dampener 142 can select corrective signals to apply, to the mover, at each time slice of the movement (and post-movement) of the mover.

In some implementation, dampener 142 can apply one or move formulas to the input signals to determine a corrective signal(s) to reduce or remove the oscillations in the substrate.

In some implementation, dampener 142 can be configured to use a notch filter. A notch filer is a type of band-stop filter, which is a filter that attenuates frequencies within a specific range while passing all other frequencies unaltered. In such implementations, dampener 142 can determine the frequency generated by the substrate based on the mover movement data, the substrate data, and/or the environmental data. For example, dampener 142 can use one or more formula, perform one or more derivative operations, etc. to determine the frequency of the vibration produced by the substrate. Responsive to the frequency being within a specific range, dampener 142 can apply one or more corresponding corrective signals. Responsive to the frequency being outside the specific range, dampener 142 elect not to apply the corrective signal(s).

Data store 150 can be a memory (e.g., random access memory), a drive (e.g., a hard drive, a flash drive), a database system, or another type of component or device capable of storing data. Data store 150 can include multiple storage components (e.g., multiple drives or multiple databases) that can span multiple computing devices (e.g., multiple server computers). The data store 150 can store data associated with processing a substrate at manufacturing equipment 100. For example, data store 150 can also store mover movement data during movement operations, such as, the mover start time, the mover acceleration rate, etc. In some implementations the mover movement data can be preprogrammed data related to a recipe, to movement operations of the magnetic levitation track, etc.

Data store 150 can also store data collected by sensors at manufacturing equipment before, during, or after a substrate process (referred to as process data). Process data can refer to historical process data (e.g., process data generated for a prior substrate processed at the manufacturing system) and/or current process data (e.g., process data generated for a current substrate processed at the manufacturing system). Data store 150 can also store spectral data or non-spectral data associated with a portion of a substrate processed at manufacturing equipment 100. Spectral data can include historical spectral data and/or current spectral data.

In some implementations, one or more portions of data stored at data store 150 can be encrypted using an encryption mechanism that is unknown to the user (e.g., data is encrypted using a private encryption key). In other or similar implementations, data store 150 can include multiple data stores where data that is inaccessible to the user is stored in one or more first data stores and data that is accessible to the user is stored in one or more second data stores.

FIG. 2A depicts a magnetic levitation platform 200 according to one or more embodiments described herein. As shown, first longitudinal magnetic levitation track 202 runs along a bottom surface of transfer chamber 214. Second and third longitudinal magnetic levitation tracks 204 and 206, respectively, also run along the bottom surface of transfer chamber 214, parallel to the first longitudinal track 202. A linear motor (not shown) may be located beneath the bottom surface of the transfer chamber 214. The linear motor may generate motive force by a stator. Arranged perpendicularly to longitudinal tracks 202, 204, 206 are lateral tracks 208, 210, 212. In the implementations depicted in FIG. 2A, the longitudinal tracks 202, 204, 206 are in a face up orientation at a first height. The lateral tracks 208, 210, 212 may be in a face up orientation at the first height, or in a face down orientation at a second height above the first height. While the longitudinal tracks 202, 204, 206 can be supported by a bottom surface of chamber 214, the lateral tracks 208, 210, 212 can be supported by a top and/or side surfaces (not shown) of chamber 214.

One or more substrate carriers 216, 218, 220 are configured to move back and forth on the longitudinal tracks 202, 204, 206 and lateral tracks 208, 210, 212. Substrate carriers 216, 220 can be configured to move on lateral tracks 208, 210 above while substrate carrier 218 moves on track 204 below. In some implementations, substrate carriers 216, 218, 220 can be configured to vertically lift, lower and/or rotate at one or more junction 222, 224, 226, 228, 230, 232, 234, 236, 238. A junction 222, 224, 226, 228, 230, 232, 234, 236, 238 is formed where a longitudinal track 202, 204, 206 intersects a lateral track 208, 210, 212 as shown in FIG. 2A. A substrate carrier 216, 218, 220 can rotate, e.g., 90°, at a junction 222, 224, 226, 228, 230, 232, 234, 236, 238 to move from a longitudinal track 202, 204, 206 to a lateral track 208, 210, 212 and correspondingly change directions. In some implementations, the magnetic levitation platform 200 is configured to lift and/or rotate a substrate carrier 216, 218, 220 at the junctions.

In some implementation, substrate carriers 216, 218, 220 can include a pair of actuators, one for providing a vertical lift/lower function of the substrate carrier and another actuator for providing a rotation function of the substrate carrier or a turntable thereon. Magnetic bearings positioned on the outside of the turntable and may be configured to engage with the magnetic levitation tracks. For example, the substrate carrier may have a drive on the outside for lifting/lowering and a drive on the inside (e.g., within a center shaft) for rotation.

In some implementations, one or more lift pin assemblies can be used to lift and lower a substrate carrier from a bottom track to an upper track, or vice versa. The lift pin assemblies may be isolated from atmosphere using bellows. Each lift pin assembly can have a set of lift pins that can lift a substrate carrier from the bottom track to the top track and/or substrate the substrate carrier from the top track to the bottom track. When the substrate carrier with the substrate attached thereto reaches a certain proximity to the top magnetic levitation track (e.g., sensed by a track sensing system), the top track may activate a magnetic field in the proximity of the substrate carrier, securing the substrate carrier to the top track.

In some implementations, the substrate carrier is configured to move from a lower track to an upper track without a lift pin assembly. For example, the substrate carrier having magnets on a top surface and a bottom surface thereof utilizes magnetic attraction between the magnets and a respective magnetic levitation track to switch tracks. In some implementations, a substrate carrier operating on a lower longitudinal track, such that a magnet on a bottom surface of the substrate carrier is engaged with the longitudinal track, can switch to an upper lateral track at a junction. A magnet on a top surface of the substrate carrier can engage with the lateral track, while at the same time disengaging with the lower longitudinal track moving the substrate carrier gently upward toward the upper lateral track. The same process may be followed to lower a substrate carrier from an upper lateral track to a lower longitudinal track.

In some implementations, lateral tracks 208, 210, 212 can align with corresponding slit valves (not shown) and corresponding process chambers (not shown), so that tracks 208, 210, 212 can be used to load and unload substrates within the process chambers, while the longitudinal tracks 202, 204, 206 are utilized by substrate carriers 216, 218, 220 to move substrates along the length of transfer chamber 214. For example, loading and unloading of substrates within the process chambers can occur on the upper lateral tracks independent of the lower longitudinal lanes below. In some implementations, a substrate carrier 216, 218, 220 moving on track, e.g., 202 can switch to, e.g., track 210 at junction 228 and move along track 210 to junction 232 proximate a slit valve and process chamber. Similarly, process chambers and/or load locks can be positioned at either end of the longitudinal tracks 202, 204, 206 and a substrate carrier 216, 218, 220 can move from one end of the transfer chamber 214 to the other end of the transfer chamber to place substrates in a process chamber at the opposite end. In at least one embodiment, substrate carriers 216, 218, 220 can include turntables (not shown) positioned thereon such that the turntables are integrated with the frame body (e.g., stationary turntables) of the transfer chamber or transfer tunnel.

One benefit of utilizing a magnetic levitation platform with at least three (3) longitudinal tracks 202, 204, 206 and/or at least three lateral tracks 208, 210, 212 is to prevent the blocking of a longitudinal lane upon rotation of a substrate carrier by 90°. As shown in FIG. 2A, substrate carrier 216 has rotated at junction 228 and overlies both longitudinal track 202 and longitudinal track 204. However, longitudinal track 206 remains unobstructed and can continue to operate while substrate carrier 216 is in the process of moving either vertically or laterally.

Some implementations of a substrate carrier 216 suitable for use with a modular linear magnetic levitation track 252 is shown in FIG. 2B. The modular linear magnetic levitation track 252 can be positioned within a linear transfer tunnel (not shown). For example, opposite ends of the transfer tunnel can include one or more slit valves accessible to one or more process chamber, process chamber cluster, load lock, etc. One or more substrate carriers 200 can be configured to move between opposite ends of the liner transfer tunnel to pick and place substrates between the process chambers, clusters, load locks, etc.

Substrate carrier 216 can include a mover 251 on which a rotating disc 254 can be positioned. Along at least two sides of the mover 251, are a pair of stationary coils 256A, 256B. Stationary coils 258 can be positioned beneath mover 251 along the middle of mover 251 and between magnetic levitation tracks 252. Substrate carrier 216 can be configured to move linearly along magnetic levitation track 252 and to rotate substrate arm 260, for example, from about ±90° to about ±180° to enable the substrate carrier 216 to either change directions and/or place a substrate within a process chamber (not shown). Stationary coils 258 are useful to provide linear motion of the substrate carrier 216 and substrate arm 260.

Rotating disc 254 can include a stationary active bearing (not shown) and corresponding drive parts (not shown). Substrate carrier 216 can be considered a pure passive carrier. Rotating disc 254 can further include a passive rotational magnetic bearing 256 on a top surface thereof, which can be configured to provide rotation angles of up to about ±180°.

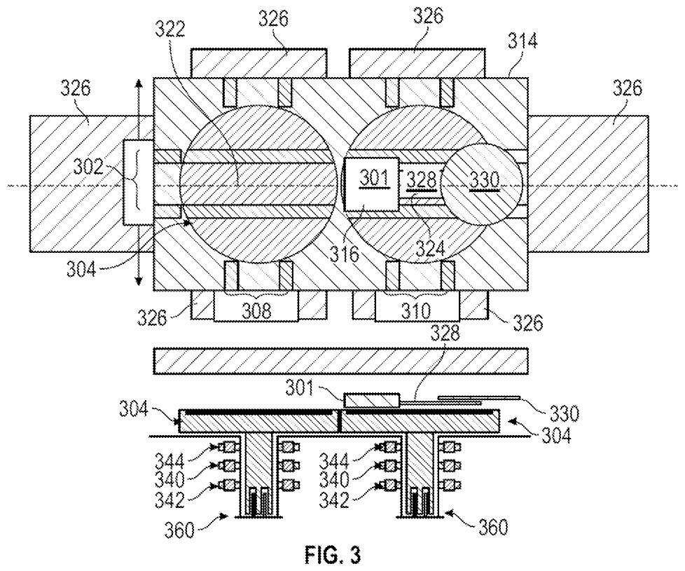

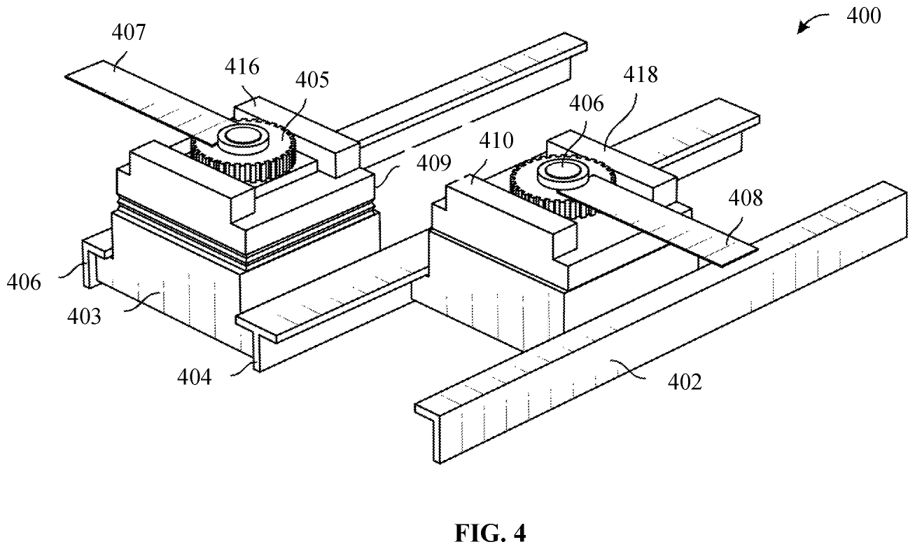

FIG. 3 is an illustration of an example magnetic levitation platform 300, in accordance with implementations of the present disclosure. Arranged around transfer chamber 314 is a set of process chambers and/or load locks 326. Longitudinal magnetic levitation tracks 302 run along the length of the transfer chamber 314 at a first height within transfer chamber 314. Located at opposite ends of longitudinal magnetic levitation tracks 302 are process chambers 326. Substrate carrier 316 is configured to move linearly along longitudinal tracks 302 between the process chambers 326 at each end. Substrate carrier 316 can be any suitable carrier as described herein. Running perpendicular to longitudinal tracks 302 are lateral magnetic levitation tracks 308, 310. Located at opposite ends of each of the lateral tracks 308, 310 are process chambers 326. Substrate carrier 316 also is configured to move linearly along lateral tracks 308, 310. Lateral tracks 308, 310 can be at a second height within transfer chamber 314, below the first height.

The plane of each lateral track 308, 310 intersects the plane of longitudinal tracks 302 at junctions 322, 324. Substrate carrier 316 can move between longitudinal tracks 302 and lateral tracks 308, 310 at junctions 322, 324. Turntable 304 is configured to rotate substrate carrier 316 up to about ±180°. Substrate carrier 316 can include a mover 301 having end effector 328 attached thereto and configured to support substrate 330. In some implementations, turntable 304 can be driven by a direct drive 340 coupled with lower bearings 342 and upper bearings 344. As such, turntable 304 can be supplied with power to operate the direct drive 340.

In some implementations, turntable 304 is capable of performing a vertical lift (e.g., moving vertically). In some implementations, actuator 360 is provided to move the turntable 304 vertically. The turntable may have a rotational axis, can be magnetically levitated, and can be moved vertically by actuator 360. Accordingly, the mover can be switched between an upper and lower track.

FIG. 4 is an illustration of a magnetic levitation platform 400 and corresponding substrate carriers 416, 418. Magnetic levitation platform 400 includes a plurality of magnetic levitation tracks 402, 404, 406 along which substrate carriers 416, 418 that can move in a linear direction. Substrate carriers 416, 418 each include mover 403 and rotational bearings 405, 406 which are attached to end effectors 407, 408. Mover 403 are operable by a standard energy coupling (e.g., an electrical wire) and moving magnets (not shown). In some implementations, a transfer chamber or tunnel in which platform 400 resides can include passive platform 409, 410 for rotation and linear motion on a top surface of the chamber or tunnel. Platform 400 can further include a lift assembly (e.g., lift pin assembly) to lift passive platform 409, 410 from within the carrier 416, 418, which is sealed by a bellow. Though not shown, an additional set of magnetic levitation tracks can be positioned above the substrate carriers 416, 418, which can be longitudinal or lateral magnetic levitation tracks. The substrate carriers 416, 418 can be moved between the upper and lower magnetic levitation tracks.

FIGS. 5A-B are illustrations of a magnetic levitation platform 500, according to aspects of the present disclosure. Platform 500 includes magnetic levitation track 502, mover 504, end effector 506, and substrate 508. Mover 504 can levitate along magnetic levitation track 502 to move the substrate carrier (which in turn moves substrate 508) in the horizontal direction (x-axis). Mover 504 can also lift and/or lower substrate 508 in the vertical direction (z-axis) using, for example, a vertical motion assembly (e.g., vertical motion assembly 128A-128E of FIG. 1B-C). In some implementations, mover 504 can raise and/or lower end effector 506 using, for example, magnetic or mechanical forces.

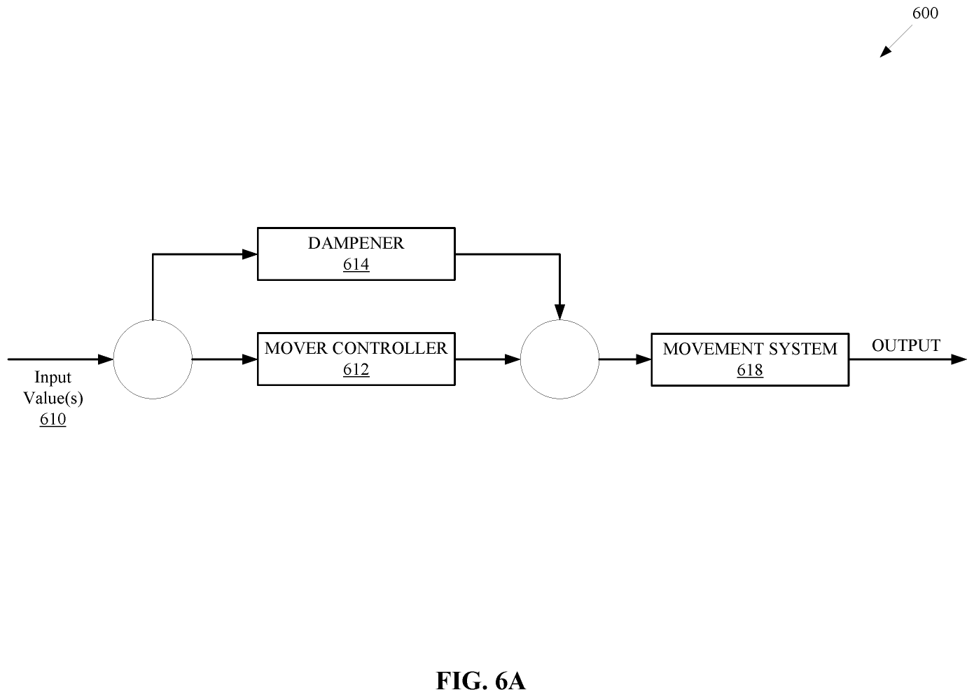

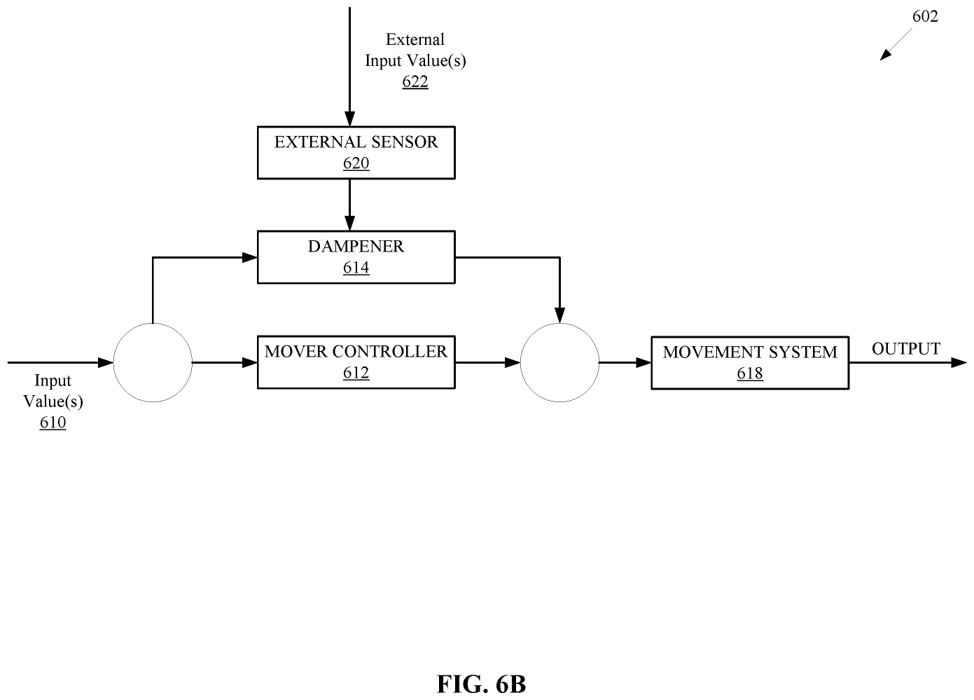

FIG. 6A is block diagram of an example system controller 600, according to certain implementations. System controller 600 can be similar to or the same as system controller 140. System controller 600 can include mover controller 612, dampener 614, and movement system 618. Dampener 614 can be similar to or the same as dampener 142. Movement system 618 can include one or more of a mover, a magnetic levitation track, etc.

Mover controller 612 and dampener 614 can each receive one or more respective input values 610. In particular, mover controller 612 can receive one or more input values indicating, for example, which mover to move, the current position of the mover, the target position of the mover, etc. Dampener 614 can receive one or more input values indicating movement data, substrate data, environment data, etc.

Based on the received input data, mover controller 612 can determine, for the selected mover, an acceleration rate, decelerations rate, time of acceleration, time to cease acceleration, time of deceleration, etc. For example, mover controller 612 can use a reference table (e.g., a metadata table) to determine the current value, the voltage values, the polarity, etc. to apply to one or more coils and/or one or more bearings of the mover and/or the magnetic levitation track. Dampener 614 can, based on its received input data, determine one or more corrective signals to apply to movement system 618 (e.g., to the coils and/or bearings of the mover and/or magnetic levitation track). The corrective signals can be used to reduce the vibration of the substrate during and after transit. For example, dampener 614 can apply a respective current, obtained from the reference table, during each time slice during and after transit of the substrate to alter the levitation of the mover (or raise or lower the end effector) such that the altered levitations (e.g., raising and/or lowering the mover) dampen the vibrations experienced by the substrate.

FIG. 6B is block diagram of another example system controller 602, according to certain implementations. System controller 600 can be similar to or the same as system controller 140. System controller 600 can include mover controller 612, dampener 614, movement system 618, and external sensor 620. Dampener 614 can be similar to or the same as dampener 142. Movement system 618 can include one or more of a mover, a magnetic levitation track, etc.

In some implementations, system controller 600 can use one or more external sensors 620 to obtain external input data 622 for dampening operations. Sensor(s) 620 can include an accelerometer, a motion sensor, a shock sensor, a tilt sensor, a vibration sensor, a gyroscope, etc. Sensor 620 can be mounted, for example, outside of the transfer chamber (e.g., transfer chamber 102), outside of the manufacturing system, etc. Dampener 614 can, based on external input data 622 obtained from sensor 620, modify the corrective signals that were determined based on the input values 610, or determine additional corrective signals. Dampener 614 can use a reference table, a formula, a calculation, etc. to determine the modifications or additional corrective signals. In an illustrative example, sensor 620 can be configured to detect vibrations (e.g., caused by earthquakes, external pumps, vehicles passing by, or any other vibrations originating outside of the transfer chamber). Responsive to sensor 620 sensing these vibrations, dampener 614 can receive the data (e.g., accelerometer data), and modify the current corrective signals or determine and apply additional corrective signals.

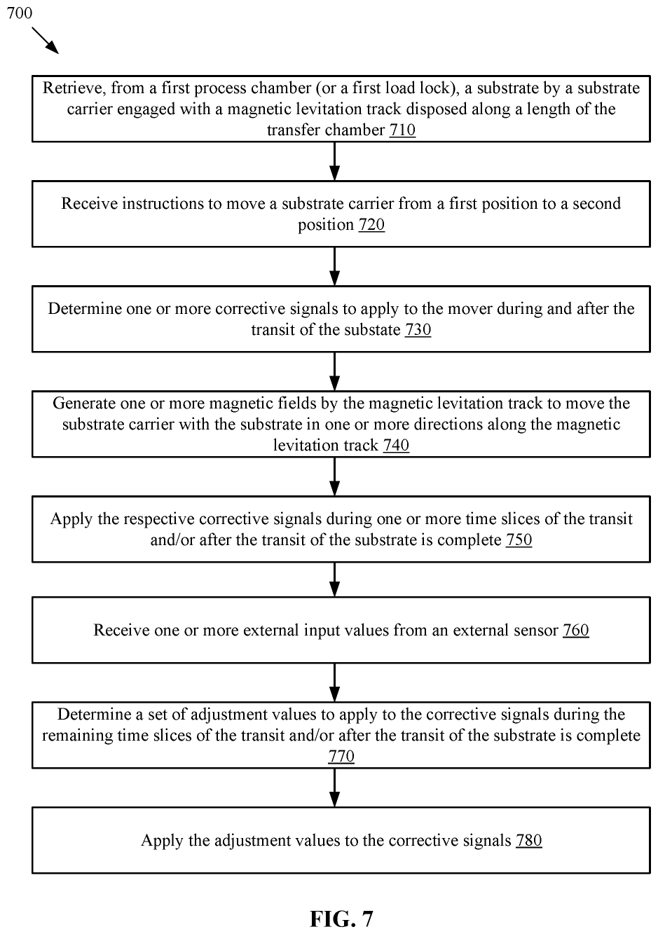

FIG. 7 is a flow chart of a method 700 for performing damping operations on the substrate carrier, according to aspects of the present disclosure. Method 700 is performed by processing logic that can include hardware (circuitry, dedicated logic, etc.), software (such as is run on a general-purpose computer system or a dedicated machine), firmware, or some combination thereof. In one implementation, method 700 can be performed by a computer system, such as system controller 140 of FIG. 1. In other or similar implementations, one or more operations of method 700 can be performed by one or more other machines not depicted in the figures.

At operation 710, processing logic retrieves, from a first process chamber (or a first load lock), a substrate by a substrate carrier engaged with a magnetic levitation track disposed along a length of the transfer chamber. The magnetic levitation track can be configured to generate a first magnetic field above the first magnetic levitation track.

At operation 720, processing logic receives instructions to move a substrate carrier from a first position to a second position. The substrate carrier can include a mover and an end effector holding a substrate. The instructions can include mover movement data. For example, the instructions can include one or more of the initial position of the mover, the final position of the mover, the movement start time, the movement end time, the movement direction of the mover (e.g., vertical movement, horizontal movement, etc.), the acceleration rate of the mover, the deceleration rate of the mover, the velocity of the mover, etc.

At operation 730, processing logic determines one or more corrective signals to apply to the mover during and after the transit of the substrate. In some implementations, the processing logic can first receive or obtain (e.g., from data store 150) substrate data and/or environmental data. The substrate data can include the mass or weight of the substrate, the center of gravity of the substrate, etc. The substrate related data can be obtained from a data store (e.g., data store 150) and/or obtained from one or more sensors (e.g., a sensor positioned on the substrate carrier). In some implementations, the processing logic can perform a lookup in a reference table to determine the corresponding corrective signal(s) based on the mover movement data, the substrate data, and/or the environmental data. The processing logic can select a corrective signal(s) to apply during one or more time slices of the transit and after the transit of the substrate. The corrective signal can include a current, voltage, an instruction, etc. to adjust the position (e.g., levitation) of the mover (e.g., raise the mover, lower the mover, etc.) or of the end effector (e.g., raise the mover, lower the mover, etc.).

At operation 740, processing logic generates one or more magnetic fields by the magnetic levitation track to move the substrate carrier with the substrate in one or more directions along the magnetic levitation track. The one or more magnetic field can be configured to move the substrate carrier along the magnetic levitation track, rotate the substrate carrier at a junction, move the substrate carrier along another (e.g., perpendicular) levitation track, etc.

At operation 750, processing logic applies the respective corrective signals during one or more time slices of the transit and/or after the transit of the substrate is complete. The corrective signals can reduce or prevent vibrations in the substrate during and/or after transit.

In some implementations, one or more external sensors (e.g., sensor 620) can be configured to monitor for external signals (e.g., external vibrations). According, in such implementations, at operation 760, processing logic receives one or more external input values from an external sensor. The external sensor can include an accelerometer, a motion sensor, a shock sensor, a tilt sensor, a vibration sensor, a gyroscope, etc.

At operation 770, processing logic determines a set of adjustment values to apply to the corrective signals during the remaining time slices of the transit and/or after the transit of the substrate is complete. In some implementations, the processing logic can use a reference table, a formula, a calculation, etc. to determine the adjustment values. The adjustment values can include modification values (e.g., values to apply to the corrective signals to modify the corrective signals), new corrective values to apply during the remaining time slices during and/or after transit, etc.

At operation 780, processing logic applies the adjustment values to the corrective signals.

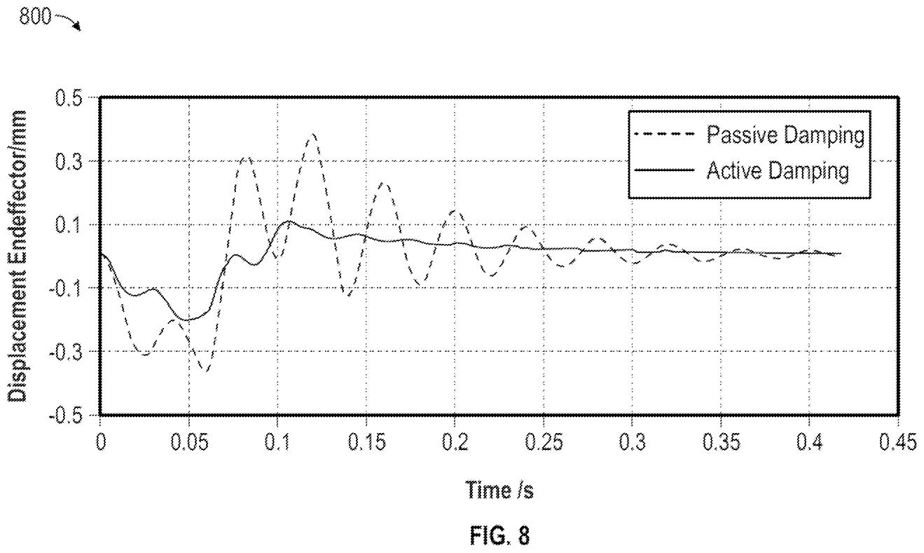

FIG. 8 is a graph 800 illustrating end effector displacement during active damping and passive damping, according to certain implementations. In particular, as shown in graph 800, passive damping (e.g., using a mechanical device or a fluid to reduce vibration) causes the end effector do experience significant larger displacement as comparted to active damping (e.g., using input data to dampen the vibrations, as described in relation to the implementation herein).

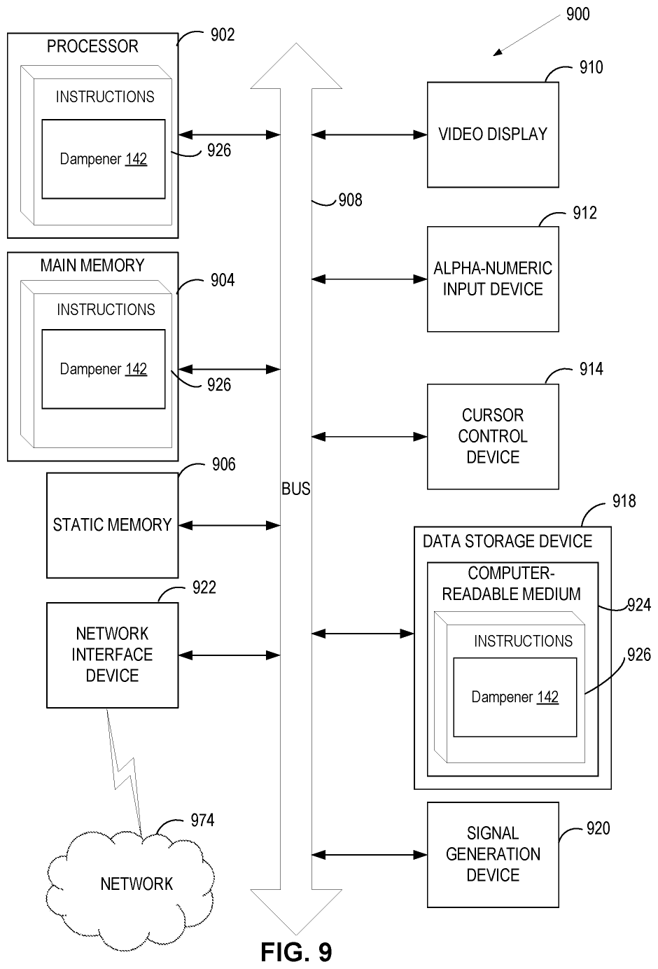

FIG. 9 is a block diagram illustrating a computer system 900, according to certain implementations. In some implementations, computer system 900 can be connected (e.g., via a network, such as a Local Area Network (LAN), an intranet, an extranet, or the Internet) to other computer systems. Computer system 900 can operate in the capacity of a server or a client computer in a client-server environment, or as a peer computer in a peer-to-peer or distributed network environment. Computer system 900 can be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 900 can include a processing device 902, a volatile memory 904 (e.g., Random Access Memory (RAM)), a non-volatile memory 906 (e.g., Read-Only Memory (ROM) or Electrically-Erasable Programmable ROM (EEPROM)), and a data storage device 916, which can communicate with each other via a bus 908.

Processing device 902 can be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 900 can further include a network interface device 922 (e.g., coupled to network 974). Computer system 900 also can include a video display unit 910 (e.g., an LCD), an alphanumeric input device 912 (e.g., a keyboard), a cursor control device 914 (e.g., a mouse), and a signal generation device 920.

In some implementations, data storage device 916 can include a non-transitory computer-readable storage medium 924 on which can store instructions 926 encoding any one or more of the methods or functions described herein, including instructions encoding components of FIG. 1 (e.g., a chucking module (not shown) of the system controller 128), a de-chucking module (not shown) of system controller 128, etc.) and for implementing methods described herein. In some implementations, the chucking module can perform the operations of method 300. In some implementations, the de-chucking module can perform the operations of method 400.

Instructions 926 can also reside, completely or partially, within volatile memory 904 and/or within processing device 902 during execution thereof by computer system 900, hence, volatile memory 904 and processing device 902 can also constitute machine-readable storage media.

While computer-readable storage medium 924 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein can be implemented by discrete hardware components or can be integrated in the functionality of other hardware components such as ASICS, FPGAs, DSPs or similar devices. In addition, the methods, components, and features can be implemented by firmware modules or functional circuitry within hardware devices. Further, the methods, components, and features can be implemented in any combination of hardware devices and computer program components, or in computer programs.

Unless specifically stated otherwise, terms such as “receiving,” “performing,” “providing,” “obtaining,” “causing,” “accessing,” “determining,” “adding,” “using,” “training,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and cannot have an ordinal meaning according to their numerical designation.

Examples described herein also relate to an apparatus for performing the methods described herein. This apparatus can be specially constructed for performing the methods described herein, or it can include a general purpose computer system selectively programmed by a computer program stored in the computer system. Such a computer program can be stored in a computer-readable tangible storage medium.

The methods and illustrative examples described herein are not inherently related to any particular computer or other apparatus. Various general purpose systems can be used in accordance with the teachings described herein, or it can prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

1. A method, comprising:
receiving, by a processor, a set of input values associated with moving a substrate carrier from a first position to a second position along a magnetic levitation track;
determining, based on the set of input values, one or more corrective signals to apply to the substrate carrier during movement of the substrate carrier along the magnetic levitation track;
generating a magnetic field to move the substrate carrier on a direction along the magnetic levitation track; and
applying, to the substrate carrier, the one or more corrective signals to reduce vibrations that would be experienced by a substrate held by the substrate carrier due to a motion of the substrate carrier.

2. The method of claim 1, further comprising:
determining, based on the set of input values, one or more corrective signals to apply to the substrate carrier after the movement of the substrate carrier ceases.

3. The method of claim 1, wherein the one or more corrective signals are determined by performing a lookup in a reference table.

4. The method of claim 1, further comprising:
obtaining substrate data associated with one or more properties of the substrate; and
determining the one or more corrective signals based on the set of input values and the substrate data.

5. The method of claim 1, further comprising:
obtaining sensor data from a sensor; and
adjusting the corrective signals based on the sensor data.

6. The method of claim 1, wherein the one or more corrective signals are applied to at least one of the substrate carrier, the magnetic levitation track, or an end effector coupled to the substrate carrier.

7. The method of claim 1, wherein the one or more corrective signals adjust an elevation of at least one of the substrate carrier, the magnetic levitation track, or an end effector coupled to the substrate carrier.

8. An electronic device manufacturing system, comprising:
a substrate carrier configured to secure a substrate; and
a controller, operatively coupled to the substrate carrier, the controller configured to perform operations comprising:
receiving, a set of input values associated with moving the substrate carrier from a first position to a second position along a magnetic levitation track;
determining, based on the set of input values, one or more corrective signals to apply to the substrate carrier during movement of the substrate carrier along the magnetic levitation track;
generating a magnetic field to move the substrate carrier on a direction along the magnetic levitation track; and
applying, to the substrate carrier, the one or more corrective signals to reduce vibrations that would be experienced by a substrate held by the substrate carrier due to a motion of the substrate carrier.

9. The electronic device manufacturing system of claim 8, wherein the operations further comprise:
determining, based on the set of input values, one or more corrective signals to apply to the substrate carrier after the movement of the substrate carrier ceases.

10. The electronic device manufacturing system of claim 8, wherein the one or more corrective signals are determined by performing a lookup in a reference table.

11. The electronic device manufacturing system of claim 8, wherein the operations further comprise:
obtaining substrate data associated with one or more properties of the substrate; and
determining the one or more corrective signals based on the set of input values and the substrate data.

12. The electronic device manufacturing system of claim 8, wherein the operations further comprise:
obtaining sensor data from a sensor; and
adjusting the corrective signals based on the sensor data.

13. The electronic device manufacturing system of claim 8, wherein the one or more corrective signals are applied to at least one of the substrate carrier, the magnetic levitation track, or an end effector coupled to the substrate carrier.

14. The electronic device manufacturing system of claim 8, wherein the one or more corrective signals adjust an elevation of at least one of the substrate carrier, the magnetic levitation track, or an end effector coupled to the substrate carrier.

15. A non-transitory computer-readable storage medium comprising instructions that, when executed by a processing device operatively coupled to a memory, performs operations comprising:
receiving a set of input values associated with moving a substrate carrier from a first position to a second position along a magnetic levitation track;
determining, based on the set of input values, one or more corrective signals to apply to the substrate carrier during movement of the substrate carrier along the magnetic levitation track;
generating a magnetic field to move the substrate carrier on a direction along the magnetic levitation track; and
applying, to the substrate carrier, the one or more corrective signals to reduce vibrations that would be experienced by a substrate held by the substrate carrier due to a motion of the substrate carrier.

16. The non-transitory computer-readable storage medium of claim 15, wherein the operations further comprise:
determining, based on the set of input values, one or more corrective signals to apply to the substrate carrier after the movement of the substrate carrier ceases.

17. The non-transitory computer-readable storage medium of claim 15, wherein the one or more corrective signals are determined by performing a lookup in a reference table.

18. The non-transitory computer-readable storage medium of claim 15, wherein the operations further comprise:
obtaining substrate data associated with one or more properties of the substrate; and
determining the one or more corrective signals based on the set of input values and the substrate data.

19. The non-transitory computer-readable storage medium of claim 15, wherein the operations further comprise:
obtaining sensor data from a sensor; and
adjusting the corrective signals based on the sensor data.

20. The non-transitory computer-readable storage medium of claim 15, wherein the one or more corrective signals are applied to at least one of the substrate carrier, the magnetic levitation track, or an end effector coupled to the substrate carrier.
